(19) United States
(12) Patent Application Publication
(10) Pub. No.: US 2012/0230079 A1
(43) Pub. Date: Sep. 13, 2012

(54) ACTUATOR AND STORAGE DEVICE

(75) Inventors: Yongfang Li, Kanagawa-ken (JP); Yasushi Tomizawa, Tokyo (JP); Hiroaki Nakamura, Kanagawa-ken (JP); Akihiro Koga, Tokyo (JP)

(73) Assignee: KABUSHIKI KAISHA TOSHIBA, Tokyo (JP)

(21) Appl. No.: 13/235,652

(22) Filed: Sep. 19, 2011

(30) Foreign Application Priority Data
Mar. 8, 2011 (JP) P2011-050843

(51) Int. Cl. G11C 11/22; H02N 1/00

(52) U.S. Cl. 365/145; 310/300

(57) ABSTRACT

In one embodiment, an actuator has a movable member, a frame, and first and second electrodes. Each of the first electrodes has a pair of first and second planes perpendicular to a third direction which is orthogonal to the first and the second directions approximately. The second electrodes are provided alternately with the first electrode respectively and with a distance from the first electrode. Each of the second electrodes has a pair of third and fourth planes perpendicular to the third direction. The first and the second planes have a deviation in the third direction with respect to the third and the fourth planes, respectively. The amount of the deviation is larger than a maximum value of the amount of displacement of the movable member in the third direction. The amount of displacement is produced by gravity when a component of the gravity in the third direction is maximum.

### CROSS-REFERENCE TO RELATED APPLICATION(S)

This application is based upon and claims the benefit of priority from the prior Japanese Patent Application No. 2011-50843, filed on Mar. 8, 2011, the entire contents of which are incorporated herein by reference.

### FIELD

Embodiments described herein relate generally to an actuator and a storage device.

### BACKGROUND

An electrostatic comb type actuator combined with a parallel-plate actuator is proposed as a XYZ actuator. The comb type actuator drives a movable member for conveying a recording medium etc. by electrostatic force produced between comb electrodes. In the actuator, a pair of plate electrodes is oppositely arranged in a movement direction (z-axis direction) of the movable member. The movable member is driven in the movement direction, which is perpendicular to a driving direction (x-axis and y-axis directions) of the movable member within a plane.

The above electrostatic force may not be stable when a distance between the plate electrodes changes by the influence of gravity or disturbance. When the electrostatic force is unstable, the movable member can not be moved stably.

### BRIEF DESCRIPTION OF THE DRAWINGS

FIG. 1A is a perspective view schematically showing a storage device according to a first embodiment.

FIG. 1B is a plan view showing a schematic configuration of a probe unit.

FIG. 2 is an enlarged top view of an actuator which is employed in the first embodiment.

FIG. 3 is a block diagram schematically showing an electric system provided in the probe unit of the storage device.

FIG. 4 is an enlarged cross-sectional view of the storage device.

FIG. 5 shows a state of driving of the storage device in a z-axis direction.

FIG. 6 shows a state of driving of the storage device in a x-axis direction.

FIG. 7 is a perspective view schematically showing a storage device according to a second embodiment.

FIG. 8 is an enlarged cross-sectional view of the storage device shown in FIG. 7.

FIG. 9 shows a state of driving of the storage device of FIG. 7 in a x-axis direction.

### DETAILED DESCRIPTION

According to one embodiment, an actuator is provided. The actuator has a movable member, a frame, and first and second electrodes.

The movable member is capable of moving in a first direction. The movable member has a first side surface parallel with a second direction which is different from the first direction. The frame is provided with a distance from the movable member. The frame has a second side surface opposite to the first side surface. The frame supports the movable member movably in the first direction. The first electrodes are arranged in a comb-teeth shape on the first side surface. Each of the first electrodes has a pair of first and second planes perpendicular to a third direction which is orthogonal to the first and the second directions approximately.

The second electrodes are arranged in a comb-teeth shape on the second side surface. The second electrodes are provided alternately with the first electrode respectively and with a distance from the first electrode. Each of the second electrodes has a pair of third and fourth planes perpendicular to the third direction. The first and the second planes have a deviation in the third direction with respect to the third and the fourth planes, respectively. The amount of the deviation is larger than a maximum value of the amount of displacement of the movable member in the third direction. The amount of displacement is produced by gravity when a component of the gravity in the third direction is maximum.

Hereinafter, further embodiments will be described with reference to the drawings.

In the drawings, the same reference numerals denote the same or similar portions respectively.

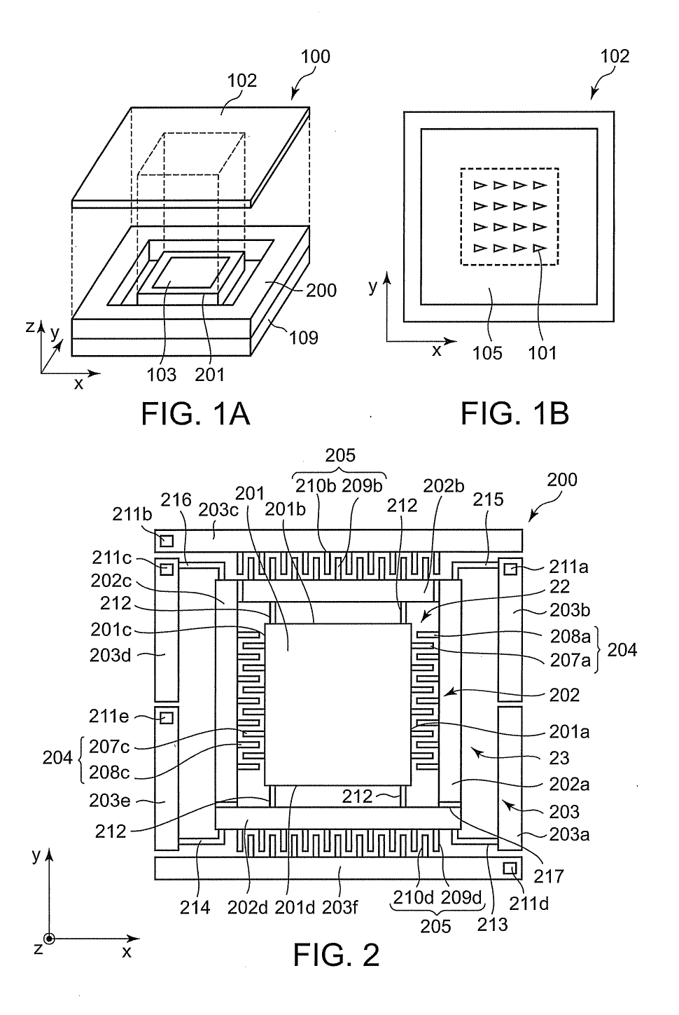

A storage device according to a first embodiment will be described with reference to FIGS. 1 to 4.

FIG. 1A is a perspective view of a schematic configuration of the storage device according to the first embodiment. FIG. 1B is a plan view showing a schematic configuration of a probe unit shown in FIG. 1A.

As shown in FIG. 1A, a storage device 100 is provided with a cap 109, a recording medium 103, a probe unit 102, and an actuator 200 having a stage 201 as a movable member. The recording medium 103 is mounted on the movable stage 201. The actuator 200 is an electrostatic drive actuator which is fixed on the cap 109. The actuator 200 is drivable in three axes.

The movable stage 201 has a rectangular plate shape. The recording medium 103 is mounted on the movable stage 201. The recording medium 103 can store data (hereinafter, referred to as “signal”). The probe unit 102 is opposes the recording medium 103 with a distance provided between the probe unit 102 and the recording medium 103. The probe unit 102 has a plurality of probes 101 arranged in a matrix on an insulating substrate 105, as shown in FIG. 1B. When the recording medium 103 is moved in the XYZ axis direction, the recording medium 103 is brought into contact with the probes 101, and a signal is read from the recording medium 103 or is written in the recording medium 103 in order to record or reproduce the signal.

The actuator 200 moves the movable stage 201 with respect to the probes 101.

The probes 101 of the probe unit 102 are arranged oppositely to the recording medium 103. An electrode is provided at each front end of the probes 101.

The probes 101 and the recording medium 103 are separated from each other during non-recording or non-reproducing of a signal when recording/reproducing is not performed.

When recording or reproducing of a signal is performed, the actuator 200 moves the recording medium 103 mounted on the movable stage 201, and brings the probes 101 into contact with the recording medium 103 as described above. Tinder the contact state, the probes 101 and the recording medium 103 perform recording or reproducing operation of the signal when a predetermined voltage is applied to the electrodes of the probes 101, for example.

The recording medium 103 is a thin film containing a ferroelectric material, for example, and stores an electrically changed state of the thin film as a signal. Lead zirconate titanate, for example, is preferable for the ferroelectric material.

The probe unit 102 has the probes 101 arranged in a matrix as described above. A matrix of 4×4 probes which is formed on the substrate 105 as shown in FIG. 1B will be described as an example below.

FIG. 2 is an enlarged top view of a configuration of the actuator 200.

The actuator 200 is provide with the stage 201 on which a recording medium 103 is to be mounted, a movable frame 202, and a fixed frame 203. The movable frame 202 is arranged around the stage 201 via a first space 22. The fixed frame 203 is arranged around the movable frame 202 via a second space 23. The stage 201, the movable frame 202 and the fixed frame 203 are formed of conductive materials.

The fixed frame 203 supports the movable frame 202 with conductive supporting members 213 to 216. Further, the movable frame 202 supports the stage 201 with a plurality of supporting members 212 having conductivity and elasticity.

A plane of the stage 201 is arranged along a x-y plane shown in FIG. 2. A first driving unit 204 is provided in the first space 22. The first driving unit 204 drives the stage 201 in the x-axis and z-axis directions shown in FIG. 2. A second driving unit 205 is provided in the second space 23. The second driving unit 205 drives the stage 201 and the movable frame 202 integrally in the y-axis direction.

The movable frame 202 has frame members 202a to 202d facing four side surfaces 201a to 201d of the stage 201 respectively with the first space 22 provided between the frame members and the four side surfaces. The frame members are mechanically connected to each other and are integrally formed as shown in FIG. 2. The frame members 202a to 202d are electrically insulated from adjacent frame members by insulating members 217, for examples. The frame members 202b, 202d support the stage 201 at four positions with supporting members 212 elastically.

The fixed frame 203 has six frame members 203a to 203f opposing to side surfaces of the four frame members 202a to 202d which constitute the movable frame 202 with a distance provided between the frame members 203a to 203f and the frame members 202a to 202d via the second space 23.

Specifically, a pair of the frame members 203a, 203b is arranged oppositely to the frame member 202a. The frame member 203c is arranged oppositely to the frame member 202b. A pair of frame members 203d, 203e is arranged oppositely to the frame member 202c. The frame member 203f is arranged oppositely to the frame member 202d.

The pair of frame members 203a, 203b supports the frame members 202d, 202e at one position with the conductive supporting members 213, 215 elastically, respectively. The pair of frame members 203d, 203e supports the frame members 202c, 202d at one position with the conductive supporting members 216, 214 elastically, respectively.

Electrode pads 211e, 211a, 211c for applying voltages are provided in the frame members 203e, 203b, 203d, respectively. Electrode pads 211b, 211d for applying voltages are provided in the frame members 203c, 203f, respectively. The electrode pads 211a to 211e are fixed to a peripheral portion of the substrate 105 of the probe unit 102.

The first driving unit 204 is provided with electrodes 207a, 207c and electrodes 208a, 208c respectively having the same rectangular shape. The electrodes 207a, 207c and electrodes 208a, 208c are arranged in a row of the y-axis direction at equal intervals.

The electrodes 207a, 207c are provided on the side surfaces 201a, 201c, and are extended to stretch in the x-axis direction in the first space 22. The electrodes 208a, 208c are provided on side surfaces of the frame members 202a, 202c, and are extended to project in the x-axis direction in the first space 22. In this case, preferably, the electrodes 207a, 207c and the electrodes 208a, 208c are arranged as being engaged with each other. In the arrangement, the electrodes 207a, 207c and the electrodes 208a, 208c are also arranged so as to keep a deviation in the y-axis direction by a half of an inter-electrode interval of the electrodes 207a, 207c or by a half of an inter-electrode interval of the electrodes 208a, 208c.

By applying voltages between the electrodes 207a, 207c and the adjacent electrodes 208a, 208c respectively as described below, the first driving unit 204 drives to translate the stage 201 in the x-axis direction by electrostatic force of the x-axis direction produced between the electrodes. Further, in recording or reproducing, by applying voltages to the electrodes 207a, 207c and the adjacent electrodes 208a, 208c respectively as described below, the first driving unit 204 drives to translate the stage 201 in the z-axis direction by electrostatic force of the z-axis direction working between the electrodes so that the probes 101 and the recording medium 103 can become in a contact state.

The second driving unit 205 is provided with electrodes 209b, electrodes 209d, electrodes 208b and electrodes 208d which are arranged in a row in the x-axis direction at equal intervals. These electrodes have the same rectangular shape, respectively.

The electrodes 209b, 209d are provided on side surfaces of the frame members 202b, 202d, and are extended to project in the y-axis direction in the second space 23. The electrodes 210b, 210d are provided on side surfaces of the frame members 203c, 203f, and are extended to project in the y-axis direction in the second space 23. In this case, preferably, the electrodes 209b, 209d and the electrodes 210b, 210d are arranged as being engaged with each other. In addition to the arrangement, between the electrodes 209b, 209d and the electrodes 210b, 210d, a deviation is provided by a half of the inter-electrode interval of the electrodes 209b, 209d or the electrodes 210b, 210d in the x-axis direction.

The second driving unit 205 applies voltages between the electrodes 209b, 209d and the adjacent electrodes 210b, 210d so that the second driving unit 205 drives the stage 201 and the movable frames 202b, 202d integrally so as to be translated in the y-axis direction by electrostatic force of the y-axis direction produced between the electrodes.

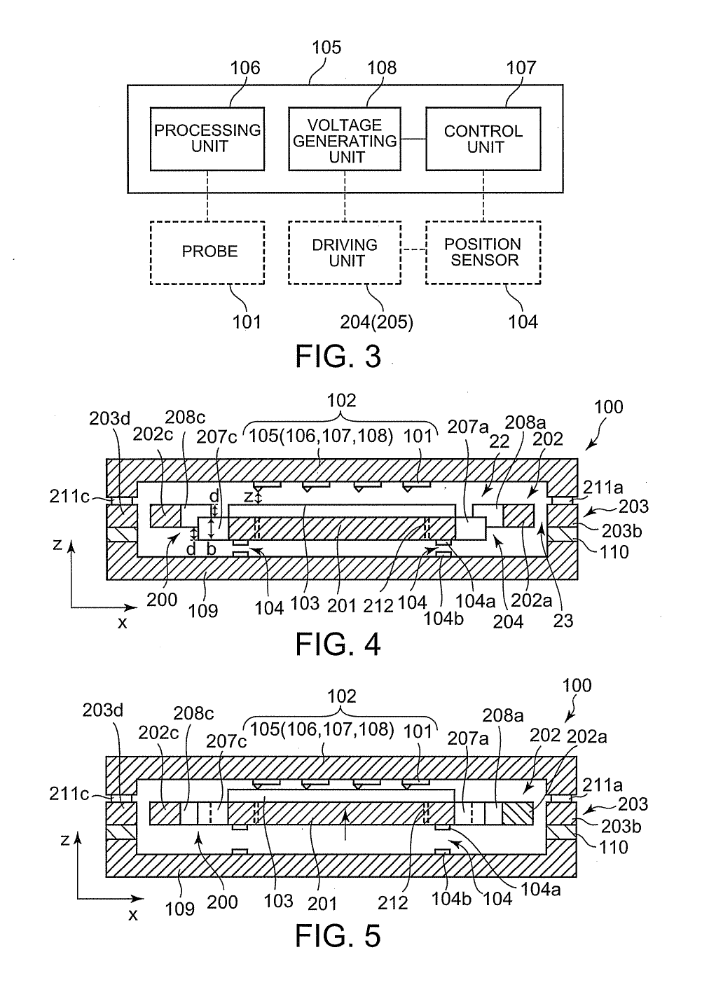

FIG. 3 shows a configuration of an electric system provided on the substrate 105 of the probe unit 102 shown in FIG. 2 schematically. A processing unit 106, a control unit 107, and a voltage generating unit 108 are provided on the substrate 105.

Position sensors 104 detect displacement of the stage 201 in the x-axis direction, the y-axis direction, and the z-axis direction. The processing unit 106 processes signals received from the probes 101. The control unit 107 calculates values of voltages to be applied to the first and second driving units 204, 205, based on detected outputs of the position sensors 104. The voltage generating unit 108 applies voltages calculated by the control unit 107, to the electrode pads 221a to 211e.

FIG. 4 is an enlarged cross-sectional view of the storage device 100 provided with the probe unit 102 and the actuator 200. FIG. 4 shows the storage device 100 of a state given at the time of non-recording or non-reproducing. The side of the probe unit 102 in the z-axis direction is defined as an upper side and the opposite side of the probe unit 102 in the z-axis direction is defined as a lower side, assuming the stage 201 as a reference.

Voltages are not applied to the electrode pads 211a to 211e in non-recording or non-reproducing. A balance exists between the self-weight of the stage 201 and the recording medium 103 mounted on the stage 201 and the elastic force of the supporting members 212. The upper and lower x-y planes or the horizontal surfaces of the respective electrodes 207a, 207c deviate from the upper and lower x-y planes or the horizontal surfaces of the respective electrodes 208a, 208c by a distance d, and the stage 201 is stationary at the lower side in the z-axis direction. In this case, d=z is satisfied preferably, where “z” represents a distance between the front ends of the probes 101 and the opposing surface of the recording medium 103 at the time of non-recording or non-reproducing.

The cap 109 shown in FIG. 4 is bonded to the actuator 200 with a bonding member 110, for example, and accommodates the recording medium 103 together with the probe unit 102. Because the cap 109 needs to be electrically insulated from the actuator 200, an insulating material is preferably used for the bonding member 110. The position sensors 104 are composed of opposite electrodes 104a, 104b provided on the stage 201 and the cap 109 respectively, as described below.

FIG. 5 is a cross-sectional view showing the storage device 100 of a state given at the time of recording or reproducing. Specifically, FIG. 5 shows a state that the stage 201 is driven in the z-axis direction and the probes 101 are brought into contact with the recording medium 103.

In recording or reproducing, the voltage generating unit 108 of FIG. 3 applies voltages to the electrodes of the driving units 204, 205 via the electrode pads 221a to 211e. As a result, the first driving unit 204 drives the stage 201 in the z-axis direction and brings the probes 101 into contact with the recording medium 103, and further drives the stage 201 in the x-axis direction (to an upper side). At the same time, the second driving unit 205 drives the stage 201 in the y-axis direction. Based on the above driving of the stage 201, relative positioning of the probes 101 is performed to the recording medium 103.

When the relative positioning is performed, displacements of the stage 201 in the x-axis, y-axis and z-axis directions are measured by using the position sensors 104. In the position sensors 104, the plate electrodes 104a is provided at four corners of the back side surface of the stage 201 opposite to the side of the recording medium 103 and the plate electrodes 104b provided at four positions of the cap 109 are arranged opposite to each other. The displacement of the stage 201 in the x-axis, y-axis and z-axis directions are measured based on changes of electrostatic capacitances produced due to changes of the mutual facing areas or the distances between the plate electrodes 104a and the plate electrodes 104b.

Then, voltages are individually or simultaneously applied to the electrodes of the probes 101 while the relative positions of the probes 101 are maintained. By the voltage supply, a recording or reproducing of a signal is performed.

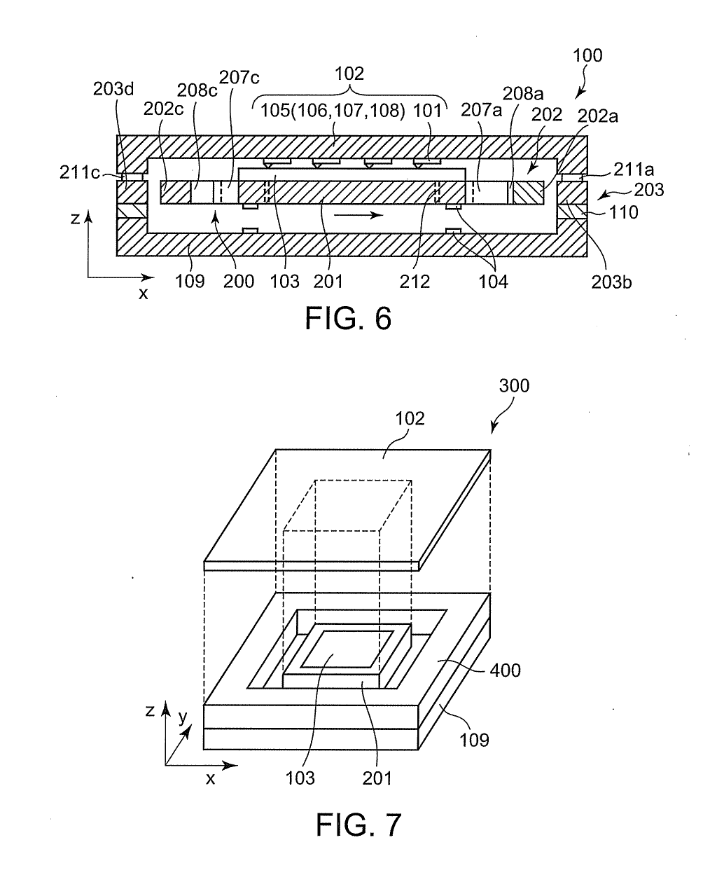

A relative positioning operation of the storage device 100 according to the embodiment will be explained in detail below with reference to FIGS. 5 and 6.

A driving in the z-axis direction will be described. The distance d shown in FIG. 4 is set, in a stationary state of the stage 201, such that h<d<b is satisfied when the storage device 100 is in a posture to maximize a z-axis direction component of the gravity of the stage 201 and the recording medium 103.

The “h” indicates a maximum amount of displacement of the stage 201 in the z-axis direction based on the gravity, or a maximum displacement amount by which the stage 201 can be displaced in the z-axis direction based on the gravity without depending on the posture of the storage device 100. The “b” indicates a width of the electrodes 207a, 207c and the electrodes 208a, 208c in the z-axis direction. The limitation of a lower limit b of the width is given to meet a condition that at least part of the electrodes 207a and at least part of the electrodes 207c face at least part of the electrodes 208a and at least part of the electrodes 208c respectively.

The voltage generating unit 108 of FIG. 3 applies voltages V1, V2 to the electrode pads 211a, 211c, respectively. At the same time, The voltage generating unit 108 applies a voltage V3 different from the voltages V1, V2 to the electrode pad 211e, or sets the electrode pad 211e at an earth potential (V3=0).

Because the electrode pad 211a is connected to the frame member 202a via the frame member 203b and the supporting member 215 as shown in FIG. 2, the voltage V1 is applied to the electrodes 208a. Because the electrode pad 211c is connected to the frame member 202c via the frame member 203d and the supporting member 216, the voltage V2 is applied to the electrodes 208c. Further, because the electrode pad 211e is connected to the stage 201 via the frame member 203e, the supporting member 214, the frame member 202d and the supporting member 212, the voltage V3 is applied to the electrodes 207a, 207c.

Accordingly, in the first driving unit 204 of FIG. 2, a potential difference (V1-V3) occurs between the electrodes 207a and the electrodes 208a which constitute the first driving unit 204 and are positioned at a right side of the x-axis direction in FIG. 5. A potential difference (V2-V3) occurs between the electrodes 207c and the electrodes 208c which constitute the first driving unit 204 and are positioned at a left side of the x-axis direction in FIG. 5.

In the first driving unit 204, electrostatic forces or attractive forces occurs between the electrodes 207a, 207c and the electrodes 208a, 208c respectively based on the potential differences. Each of the electrostatic forces has components of such directions as increasing mutual facing areas of the electrodes 207a or 207c and the electrodes 208a or 208c. The increasing directions are the x-axis direction, the z-axis direction, and the direction to attract each other i.e. the y-axis direction. The stage 201 is moved from the stationary state shown in FIG. 4 where the distance d exists, to the direction causing d=0 where the heights of the horizontal surfaces of the electrodes 207a, 207c and the electrodes 208a, 208c match each other in the z-axis direction, based on the components of the electrostatic forces of the z-axis direction. As a result, the probe 101 and the recording medium 103 are brought into contact with each other.

The electrostatic forces of the y-axis direction are not necessary to be considered in driving the stage 201 in the direction causing d=0, because the electrodes 207a, 207c and the adjacent electrodes 208a, 208c cancel electrostatic force. Further, even when the electrodes can not strictly cancel the electrostatic force, the electrostatic forces of the y-axis direction are not necessary to be considered in driving the stage 201 in the direction causing d=0. It is because the stage 201 supported by the supporting members 212 is not driven in the y-axis direction.

Driving in the x-axis direction and the y-axis direction will be explained below.

The stage 201 can be driven in the z-axis direction as well as in the x-axis and y-axis directions so that positioning of the probes 101 in the upper plane of the recording medium 103 can be performed. A driving of the stage 201 in the x-axis direction which is shown in FIG. 6 will be explained as an example.

The voltage generating unit 108 of FIG. 3 applies a voltage larger than that applied to the electrode pad 211c, to the electrode pad 211a, for example, to set V1>V2. As a result, a relationship of |V1-V3|>|V2-V3| is obtained. Accordingly, the stage 201 is driven in the x-axis positive direction, because the electrostatic force in the x-axis direction produced between the electrodes 207a and the electrodes 208a becomes larger than the electrostatic force in the x-axis direction produced between the electrode 207c and the electrode 208c.

On the other hand, a voltage larger than that applied to the electrode pad 211a is applied to the electrode pad 211c so as to set the voltage V2>the voltage V1. As a result, the stage 201 is driven in the negative direction of the x-axis, because the electrostatic force of the x-axis direction produced between the electrode 207c and the electrode 208c becomes larger than the electrostatic force of the x-axis direction produced between the electrode 207a and the electrode 208a.

Driving is performed in the y-axis direction by the voltage generating unit 108 which adjusts the electrostatic force of the y-axis direction between the electrodes 209b and the electrodes 210b and which adjusts the electrostatic force of the y-axis direction between the electrodes 209d and the electrodes 210d, in a manner similar to that of the driving in the x-axis direction.

Upper limit values of driving amounts in the x-axis and the y-axis directions can be determined in advance in a range that the electrodes 207a, 208a, the electrodes 207c, 208c, the electrodes 209b, 210b, and the electrodes 209d, 210d are not brought into contact with the opposite surfaces, respectively. The control unit 107 of FIG. 3 calculates concrete values of the application voltages V1 to V3 such that differences between the displacement amounts of the stage 201 and target values are converged to zero, using displacement amounts of the stage 201 measured by the position sensors 104, as input information.

A recording or reproducing operation of a signal will be explained below. Under the state that the probes 101 and the recording medium 103 are in a contact state as shown in FIG. 5, the stage 201 and the electrodes of the probes 101 form a plurality of localized ferroelectric capacitors via the recording medium 103 of the ferroelectric material. After the relative positioning of the probes 101 is performed to the recording medium 103 as described above, a recording or reproducing of a signal is performed while maintaining the state.

Specifically, in recording, voltages are applied between the electrodes of the probes 101 and the recording medium 103, respectively. Based on the voltage application, polarization of electric charges is produced in the recording medium 103 so that a signal is recorded. On the other hand, in reproducing, a pulse voltage is applied between the electrodes of the probes 101 and the recording medium 103. The processing unit 106 of FIG. 3 detects a current produced by polarization inversion of electric charges of the recording medium 103 so as to reproduce a signal. Voltages are individually or simultaneously applied between the probes 101 and the recording medium 103 so that a recording or reproducing of different signals can be performed.

A thin insulating film which is formed of a material such as a metal oxide may be used for the recording medium 103. In this case, a resistance change of the recording medium 103 which is produced by applying voltages to the probes 101 can be used as a signal to perform a recording or reproducing.

The actuator 200 can be made by applying lithography and etching to a silicon wafer, for example. For example, in forming the first driving unit 204, a mask is formed on one of the surfaces of the silicon wafer in order to cover regions of the silicon wafer for forming the electrodes 208a, 208c. Under the state, other regions for forming the stage 201 and the electrodes 207a, 207c are etched. Further, another mask is formed on the other of the surfaces of the silicon wafer in order to cover regions of the silicon wafer for forming the electrodes 207a, 207c. Under the state, regions for forming the electrodes 208a, 208c are etched. By the etching, the stage 201, the electrodes 207a, 207c, and the electrodes 208a, 208c can be formed.

In the storage device 100 of the embodiment, the recording medium 103 is mounted on the stage 201 of the actuator 200, and the probe unit 102 is set to oppose to the recording medium 103. The probes 101 may be provided on the stage 201 in array, and the recording medium 103 may be set on the substrate 102 which is opposite to the probes 101.

A connection relationship between the stage 201, the frame members of the movable frame 202, the frame members of the fixed frame 203, and the supporting members is not limited to that of the above example. Other connection relationships may be used so far as the electrodes 207a, 207c and the electrodes 208a, 208c are arranged in a relationship as being isolated from each other electrically and the electrodes 209b, 209d and the electrodes 210b, 210d are arranged in a relationship as being isolated from each other electrically.

Further, in addition to the above, the two horizontal surfaces of the electrodes 209b, 209d may be positioned lower in the z-axis direction than those of the electrodes 210b, 210d, by a distance d2, respectively. In this case, the horizontal surfaces are set to satisfy h2<d2<b2. “h2” indicates a maximum displacement amount by which the movable frame 202 can be displaced in the z-axis direction by gravity without depending on the posture of the storage device 100. “b2” indicates a width of the electrodes 209b and the electrodes 210b, 210d in the z-axis direction. Particularly, a relationship of d+d2=z, i.e., d2=z−d is preferable.

According to the storage device 100 of the embodiment, the electrodes 207a, 207c are positioned at the opposite side of the fixed member electrodes 208a, 208c in the z-axis direction which is a side opposite to the substrate 105, even when the stage 201 is displaced by gravity according to change of a arrangement direction of the storage device 100, for example. Accordingly, the stage 201 can be stably moved to the side of the substrate 105 in the z-axis direction by electrostatic force produced in a direction increasing mutual facing areas between the electrodes 207a, 207c and the electrodes 208a, 208c, respectively. As a result, a stable recording or reproducing of a signal can be performed. Further, the storage device 100 can prevent damage of the probes 101 which may be caused by unexpected contact between the probes 101 and the recording medium 103 by gravity of the z-axis direction.

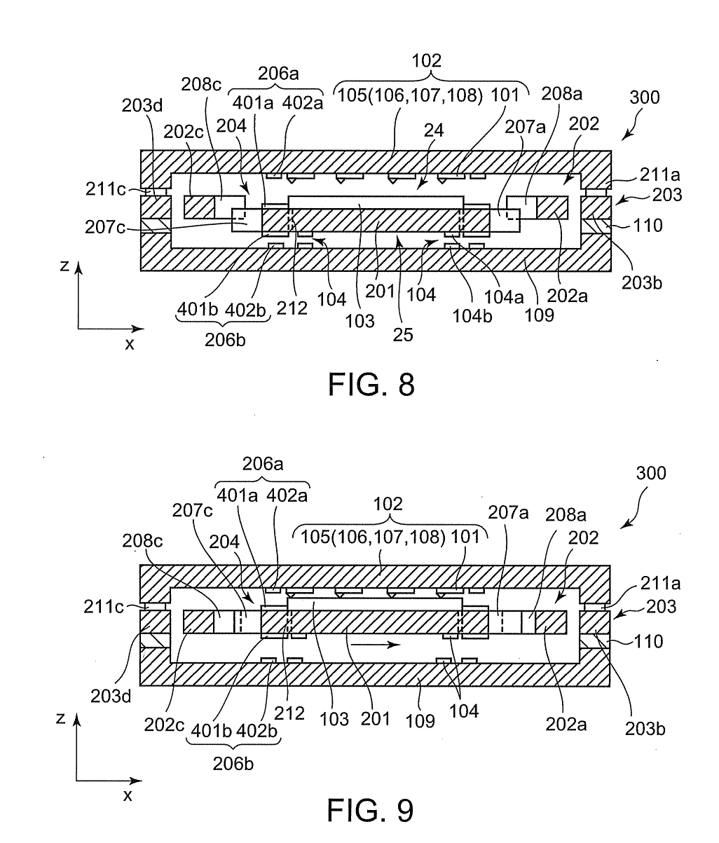

A storage device 300 according to a second embodiment will be explained in detail below with reference to FIGS. 7 to 9. FIG. 7 is a perspective view showing the storage device 300 according to the embodiment schematically. FIG. 8 is an enlarged cross-sectional view of a configuration of the storage device 300.

The storage device 300 is different from the storage device 100 of the first embodiment in that the storage device 300 is further provided with third driving units 206a, 206b as shown in FIG. 8.

The third driving unit 206a is provided on an actuator 400 and a probe unit 102 such that the third driving unit 206a is in contact with a third space 24 between the actuator 400 and the probe unit 102. Further, the third driving unit 206b is provided on the actuator 400 and the probe unit 102 such that the third driving unit 206a is in contact with a fourth space 25 between the actuator 400 and a cap 109.

The third driving unit 206a is composed of a first plate electrode 401a and a second plate electrode 402a, for example. The first plate electrode 401a is rectangular and is provided on a peripheral portion of a stage 201. The second plate electrode 402a is rectangular and is provided on the probe unit 102 opposite to the stage 201 via the third space 24. The first and the second plate electrode 401a, 402a are arranged opposite to each other and have a common center axis.

The third driving unit 206b is rectangular and is composed of a first plate electrode 401b and a second plate electrode 402b, for example. The first plate electrode 401b is rectangular and is provided on the peripheral portion of the stage 201. The second plate electrode 402b is rectangular and is provided on a cap 109 opposite to the stage 201 via a fourth space 25. The first plate electrode 401b and the second plate electrode 402b are arranged opposite to each other and have a common center axis.

In recording or reproducing, a first driving unit 204 drives the stage 201 in the z-axis direction. Then, a potential difference is applied between the plate electrodes of the third driving units 206a, 206b opposite to each other. The first driving unit 204 adjusts contact force between the probes 101 and the recording medium 103 by electrostatic force of the z-axis direction. On the other hand, in non-recording or non-reproducing, the third driving units 206a, 206b keep the distance between the probes 101 and the recording medium 103 constant by electrostatic force in the z-axis direction.

The first and the second plate electrode plate electrodes 401a, 402a have different areas, and the first and the second plate electrodes 401b, 402b have different areas. Thus, even when the stage 201 is moved to the extent of a maximum limit in the x-axis direction or the y-axis direction, the mutually facing areas between the electrodes 401a, 402a are constant, and even when the stage 201 is moved to the extent of a maximum limit in the x-axis direction or the y-axis direction, the mutually facing areas between the electrodes 401b, 402b are constant.

Accordingly, both x-axis direction end portions of the first plate electrodes 401a, 401b are positioned to be deviated to the outsides in the x-axis direction by at least an upper limit value of the driving amount of the stage 201 caused by the first driving unit 204, from both x-direction end portions of the second plate electrodes 402a, 402b, respectively. Further, both y-axis direction end portions of the first plate electrodes 401a, 401b are positioned to be deviated to the outsides in the y-axis direction by at least an upper limit value of the driving amount of the stage 201 caused by a second driving unit 205, from both the y-direction end portions of the second plate electrodes 402a, 402b, respectively.

FIG. 9 is a cross-sectional view showing a state that the first driving unit 204 drives the stage 201 in the x-axis positive direction up to the upper limit value.

Under this state, end portions of the first plate electrodes 401a, 401b located in the negative direction of the x-axis and end portions of the second plate electrodes 402a, 402b located in the negative direction of the x-axis match each other. Even when the stage 201 is moved to the upper limit value in the negative direction of the x-axis, end portions of the plate electrodes 401a, 402a and the plate electrodes 401b, 402b located in the positive direction of the x-axis match each other, in a similar manner.

When the second driving unit 205 which drives the stage 201 in the positive direction of the y-axis moves the stage 201 in the y-axis direction, the end portions of the plate electrodes match in a similar manner.

With the above arrangement, even when the first driving unit 204 and the second driving unit 205 move the stage 201, the facing areas of the first plate electrodes 401a, 401b and the second plate electrodes 402a, 402b are constant, respectively, and an electrostatic capacitance between both plate electrodes 401a, 402a and an electrostatic capacitance between both plate electrodes 401b, 402b can be kept constant, respectively. As a result, the contact force between the probes 101 and the recording medium 103 can be adjusted by a stable electrostatic force.

A detailed operation for adjusting the contact force between the probes 101 and the recording medium 103 will be described below with respect to the cases of recording, reproducing, non-recording or non-reproducing according to the second embodiment.

In recording or reproducing, a voltage generating unit 108 applies a potential difference between the first and the second plate electrodes 401a 402a and between the first and the second plate electrodes 401b, 402b, respectively. As a result, electrostatic force of the z-axis direction is produced between these electrodes. Assume that the electrostatic force produced between the first and the second plate electrodes 401a, 402a is expressed as F1 and that the electrostatic force produced between the first and the second plate electrodes 401b, 402b is expressed as F2. In this case, when F1>F2, the stage 201 is attracted to the upper side. On the other hand, when F1<F2, the stage 201 is attracted to the lower side. In this manner, the difference between the electrostatic forces F1 and F2 can be adjusted so that the contact force between the probes 101 and the recording medium 103 can be adjusted.

In non-recording or non-reproducing, the voltage generating unit 108 applies a potential difference between the first and the second plate electrodes 401a, 402a and between the first and the second plate electrode s plate electrodes 401b, 402b, respectively, so that electrostatic force of the z-axis direction is produced between these electrodes. When the electrostatic force is set as F1=F2, the stage 201 can keep a stationary state even when a direction of arranging the storage device 300 changes or even when temporary disturbance is applied to the storage device 300.

In the embodiment, the areas of the first plate electrodes 401a, 401b are set larger than those of the second plate electrodes 402a, 402b. In a case that the facing areas can be set always constant even when the stage 201 is moved, the areas of the second plate electrodes 402a, 402b may be set larger than those of the first plate electrodes 401a, 401b as described above.

The embodiments described above are capable of compensating the influence s of gravity and disturbance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An actuator comprising:
a movable member capable of moving in a first direction, the movable member having a first side surface parallel with a second direction which is different from the first direction;
a frame provided with a distance from the movable member, the frame having a second side surface opposite to the first side surface, the frame supporting the movable member movably in the first direction;
first electrodes arranged in a comb-teeth shape on the first side surface, each of the first electrodes having a pair of first and second planes perpendicular to a third direction which is orthogonal to the first and the second directions approximately; and
second electrodes arranged in a comb-teeth shape on the second side surface, the second electrodes being provided alternately with the first electrode respectively and with a distance from the first electrode, each of the second electrodes having a pair of third and fourth planes perpendicular to the third direction, wherein
the first and the second planes have a deviation in the third direction with respect to the third and the fourth planes, respectively, and the amount of the deviation is larger than a maximum value of the amount of displacement of the movable member in the third direction which is produced by gravity when a component of the gravity in the third direction is maximum.

2. An actuator comprising:
a movable member capable of moving in a first direction, the movable member having a first side surface parallel with a second direction which is different from the first direction;
a first frame provided with a distance from the movable member, the first frame having a second side surface opposite to the first side surface and a third side surface horizontal to the first direction and formed on a back side of a side surface opposite to the movable member, the first frame supporting the movable member movably in the first direction;
a second frame provided with a distance from the first frame, the second frame having a fourth side surface opposite to the third side surface, the second frame supporting the first frame movably in the second direction;
first electrodes arranged in a comb-teeth shape on the first side surface, each of the first electrodes having a pair of first and second planes perpendicular to a third direction which is orthogonal to the first and the second directions approximately;
second electrodes arranged in a comb-teeth shape on the second side surface, the second electrodes being provided alternately with the first electrodes and with a distance from the first electrodes, each of the second electrodes having a pair of third and fourth planes perpendicular to the third direction;
third electrodes arranged in a comb-teeth shape on the third side surface, each of the third electrodes having a pair of fifth and sixth planes perpendicular to the third direction;
fourth electrodes provided in a comb-teeth shape on the fourth side surface, the fourth electrodes being provided alternately with the third electrodes and with a distance from the third electrodes, each of the fourth electrodes having a pair of seventh and eighth planes perpendicular to the third direction, wherein
the first and the second planes have a first deviation in the third direction with respect to the third and the fourth planes, respectively, and the amount of the first deviation is larger than a maximum value of the amount of displacement of the movable member in the third direction which is produced by gravity when a component of the gravity in the third direction is maximum, and
the fifth and the sixth planes have a second deviation in the third direction with respect to the seventh and the eighth planes, respectively, and the amount of the second deviation is larger than a maximum value of the amount of displacement of the first frame in the third direction which is produced by gravity when a component of the gravity in the third direction is maximum

3. A storage device comprising:
a movable member capable of moving in a first direction, the movable member having a first side surface parallel with a second direction which is different from the first direction;
a first frame provided with a distance from the movable member, the first frame having a second side surface opposite to the first side surface and a third side surface horizontal to the first direction and formed on a back side of a side surface opposite to the movable member, the first frame supporting the movable member movably in the first direction;
a second frame provided with a distance from the first frame, the second frame having a fourth side surface opposite to the third side surface, the second frame supporting the first frame movably in the second direction;
first electrodes arranged in a comb-teeth shape on the first side surface, each of the first electrodes having a pair of first and second planes perpendicular to a third direction which is orthogonal to the first and the second directions approximately;
second electrodes arranged in a comb-teeth shape on the second side surface, the second electrodes being provided alternately with the first electrodes and with a distance from the first electrodes, each of the second electrodes having a pair of third and fourth planes perpendicular to the third direction;
third electrodes arranged in a comb-teeth shape on the third side surface, each of the third electrodes having a pair of fifth and sixth planes perpendicular to the third direction;
fourth electrodes provided in a comb-teeth shape on the fourth side surface, the fourth electrodes being provided alternately with the third electrodes and with a distance from the third electrodes, each of the fourth electrodes having a pair of seventh and eighth planes perpendicular to the third direction;
a substrate provided with a distance from the movable member in the third direction;
a recording medium provided at a side of the substrate of the movable member and storing information; and
a probe unit provided at the substrate side of the movable member, the probe unit having probes arranged, wherein
the first and the second planes have a first deviation in the third direction with respect to the third and the fourth planes, respectively, or the fifth and the sixth planes have a second deviation in the third direction with respect to the seventh and the eighth planes, respectively, and
the directions of the first and the second deviations are a direction toward the movable member in the third direction, assuming the substrate as a reference.

4. The storage device according to claim 3, wherein
the amount of the first deviation is larger than a maximum value of the displacement amount of the movable member in the third direction which is produced by gravity when a component of the gravity in the third direction is maximum, and the amount of the second deviation is larger than a maximum value of the displacement amount of the first frame in the third direction which is produced by gravity when a component of the gravity in the third direction is maximum.

5. The storage device according to claim 3, further comprising a first voltage generating unit, wherein
the first voltage generating unit applies a potential difference between the first and the second electrodes or between the third and the fourth electrodes, so as to move the movable member in the third direction.

6. The storage device according to claim 3, further comprising:
a cap provided with a distance from the movable member at an opposite side of the substrate with respect to the movable member;
a first plate electrode provided on the substrate;
a second plate electrode provided on the cap;
a third plate electrode provided on the movable member and arranged opposite to the first plate electrode; and
a fourth plate electrode provided on the movable member and arranged opposite to the second plate electrode.

7. The storage device according to claim 6, wherein
both end portions of the third and the fourth plate electrodes in the first direction are positioned at the first direction outsides of both end portions of the first and the second plate electrodes in the first direction, respectively, by at least an upper limit value of the movement amount of the movable member in the first direction, and both end portions of the third and the fourth plate electrodes in the second direction are positioned at the first direction outsides of both end portions of the first and the second plate electrodes in the second direction, respectively, by at least an upper limit value of the movement amount of the movable member in the second direction, or
both end portions of the first and the second plate electrodes in the first direction are positioned at the first direction outsides of both end portions of the third and the fourth plate electrodes in the first direction, respectively, by at least an upper limit value of the movement amount of the movable member in the first direction, and both end portions of the first and the second plate electrodes in the second direction are positioned at the first direction outsides of both end portions of the third and the fourth plate electrodes in the second direction, respectively, by at least an upper limit value of the movement amount of the movable member in the second direction.

8. The storage device according to claim 7, further comprising a second voltage generating unit, wherein
when the probe and the recording medium are in a non-contact state, the second voltage generating unit applies a potential difference between the first and the third plate electrodes and applies potential difference between the second and the fourth plate electrodes so that a constant distance is kept between the probe and the recording medium substantially.

9. A storage device comprising:
a movable member capable of moving in a first direction, the movable member having a first side surface parallel with a second direction which is different from the first direction;
a first frame provided with a distance from the movable member, the first frame having a second side surface opposite to the first side surface and a third side surface horizontal to the first direction and formed on a back side of a side surface opposite to the movable member, the first frame supporting the movable member movably in the first direction;
a second frame provided with a distance from the first frame, the second frame having a fourth side surface opposite to the third side surface, the second frame supporting the first frame movably in the second direction;
first electrodes arranged in a comb-teeth shape on the first side surface, each of the first electrodes having a pair of first and second planes perpendicular to a third direction which is orthogonal to the first and the second directions approximately;
second electrodes arranged in a comb-teeth shape on the second side surface, the second electrodes being provided alternately with the first electrodes and with a distance from the first electrodes, each of the second electrodes having a pair of third and fourth planes perpendicular to the third direction;
third electrodes arranged in a comb-teeth shape on the third side surface, each of the third electrodes having a pair of fifth and sixth planes perpendicular to the third direction;
fourth electrodes provided in a comb-teeth shape on the fourth side surface, the fourth electrodes being provided alternately with the third electrodes and with a distance from the third electrodes, each of the fourth electrodes having a pair of seventh and eighth planes perpendicular to the third direction;
a substrate provided with a distance from the movable member in the third direction;
a probe unit provided at a substrate side of the movable member, the probe unit having probes arranged; and
a recording medium provided at a movable member side of the substrate, the recording medium storing information, wherein
the first and the second planes have a first deviation in the third direction with respect to the third and the fourth planes, respectively, or the fifth and the sixth planes have a second deviation in the third direction with respect to the seventh and the eighth planes, respectively, and
the directions of the first and the second deviations are a direction toward the movable member in the third direction, assuming the substrate as a reference.

10. The storage device according to claim 9, wherein
the amount of the first deviation is larger than a maximum value of the displacement amount of the movable member in the third direction which is produced by gravity when a component of the gravity in the third direction is maximum, and the amount of the second deviation is larger than a maximum value of the displacement amount of the first frame in the third direction which is produced by gravity when a component of the gravity in the third direction is maximum.

11. The storage device according to claim 9, further comprising a first voltage generating unit, wherein
the first voltage generating unit applies a potential difference between the first and the second electrodes or between the third and the fourth electrodes, so as to move the movable member in the third direction.

12. The storage device according to claim 10, further comprising a first voltage generating unit, wherein
the first voltage generating unit applies a potential difference between the first and the second electrodes or between the third and the fourth electrodes, so as to move the movable member in the third direction.

13. The storage device according to claim 9, further comprising:
a cap provided with a distance from the movable member at an opposite side of the substrate with respect to the movable member;
a first plate electrode provided on the substrate;
a second plate electrode provided on the cap;
a third plate electrode provided on the movable member and arranged opposite to the first plate electrode; and
a fourth plate electrode provided on the movable member and arranged opposite to the second plate electrode.

14. The storage device according to claim 10, further comprising:
a cap provided with a distance from the movable member at an opposite side of the substrate with respect to the movable member;
a first plate electrode provided on the substrate;
a second plate electrode provided on the cap;
a third plate electrode provided on the movable member and arranged opposite to the first plate electrode; and
a fourth plate electrode provided on the movable member and arranged opposite to the second plate electrode.

15. The storage device according to claim 11, further comprising:
a cap provided with a distance from the movable member at an opposite side of the substrate with respect to the movable member;
a first plate electrode provided on the substrate;
a second plate electrode provided on the cap;
a third plate electrode provided on the movable member and arranged opposite to the first plate electrode; and
a fourth plate electrode provided on the movable member and arranged opposite to the second plate electrode.

16. The storage device according to claim 12, further comprising:
a cap provided with a distance from the movable member at an opposite side of the substrate with respect to the movable member;
a first plate electrode provided on the substrate;
a second plate electrode provided on the cap;
a third plate electrode provided on the movable member and arranged opposite to the first plate electrode; and
a fourth plate electrode provided on the movable member and arranged opposite to the second plate electrode.

17. The storage device according to claim 14, wherein
both end portions of the third and the fourth plate electrodes in the first direction are positioned at the first direction outsides of both end portions of the first and the second plate electrodes in the first direction, respectively, by at least an upper limit value of the movement amount of the movable member in the first direction, and both end portions of the third and the fourth plate electrodes in the second direction are positioned at the first direction outsides of both end portions of the first and the second plate electrodes in the second direction, respectively, by at least an upper limit value of the movement amount of the movable member in the second direction, or
both end portions of the first and the second plate electrodes in the first direction are positioned at the first direction outsides of both end portions of the third and the fourth plate electrodes in the first direction, respectively, by at least an upper limit value of the movement amount of the movable member in the first direction, and both end portions of the first and the second plate electrodes in the second direction are positioned at the first direction outsides of both end portions of the third and the fourth plate electrodes in the second direction, respectively, by at least an upper limit value of the movement amount of the movable member in the second direction.

18. The storage device according to claim 15, further comprising a second voltage generating unit, wherein,
when the probe and the recording medium are in a non-contact state, the second voltage generating unit applies a potential difference between the first and the third plate electrodes and applies potential difference between the second and the fourth plate electrodes so that a constant distance is kept between the probe and the recording medium substantially.
